(19) United States
(12) Patent Application Publication
(10) Pub. No.: US 2015/0015530 A1
(43) Pub. Date: Jan. 15, 2015

(54) TOUCH SENSING ORGANIC LIGHT EMITTING DIODE DISPLAY AND MANUFACTURING METHOD THEREOF

(71) Applicant: Samsung Display Co., Ltd., Yongin-City (KR)

(72) Inventors: Seung-Hun KIM, Yongin-City (KR); Sang-Hwan CHO, Yongin-City (KR); Chung-Sock CHOI, Yongin-City (KR); Cheol JANG, Yongin-City (KR); Hyun-Ho KIM, Yongin-City (KR); Soo-Youn KIM, Yongin-City (KR); Sang-Hyun PARK, Yongin-City (KR); Seung-Yong SONG, Yongin-City (KR)

(73) Assignee: Samsung Display Co., Ltd., Yongin-City (KR)

(21) Appl. No.: 14/059,270

(22) Filed: Oct. 21, 2013

(30) Foreign Application Priority Data
Jul. 15, 2013 (KR) 10-2013-0083014

(51) Int. Cl. G06F 3/044; H01L 51/56

(52) U.S. Cl. CPC G06F 3/044; H01L 51/56
USPC 345/174; 438/34

(57) ABSTRACT

The present disclosure relates to an organic light emitting diode (OLED) display. The organic light emitting diode (OLED) display includes an insulation substrate having a first surface and a second surface opposite to the first surface; an organic light emitting element disposed on the first surface of the insulation substrate; and an upper thin film disposed on the organic light emitting element or on the second surface of the insulation substrate, wherein the upper thin film includes a contact sensing layer and a thin multi-film adjacent to the contact sensing layer, and the thin multi-film includes at least one thin metal film and at least one dielectric layer.

### CROSS-REFERENCE TO RELATED APPLICATION

This application claims priority to and the benefit of Korean Patent Application No. 10-2013-0083014 filed in the Korean Intellectual Property Office on Jul. 15, 2013, the entire contents of which are incorporated herein by reference.

### BACKGROUND

(a) Technical Field

The present disclosure relates to a touch sensing organic light emitting diode (OLED) display and a manufacturing method thereof.

(b) Description of the Related Art

Organic light emitting display devices (OLEDs) have been identified as next generation display devices, due to their superior characteristics such as low power consumption, rapid response speed, wide viewing angles, and high contrast ratio.

An organic light emitting display device typically includes a plurality of pixels (e.g. red, blue, and green pixels). Different color images may be displayed by combining the pixels. Each pixel includes an organic light emitting element and a plurality of thin film transistors for driving the organic light emitting element.

The organic light emitting element includes a pixel electrode, a common electrode, and an emission layer disposed between the electrodes. Either the pixel electrode or the common electrode may function as an anode, with the other functioning as a cathode. The cathode injects holes and the anode injects electrons into the light emitting layer. The electrons and holes combine to form excitons, and the excitons emit light when energy is discharged. The common electrode is formed over the plurality of pixels, and a constant common voltage may be applied to the common electrode.

The organic light emitting diode (OLED) display may be classified into two types: rear emission or front emission. In a rear emission organic light emitting diode (OLED) display, light is emitted from a rear side of a substrate. In a front emission organic light emitting diode (OLED) display, light is emitted from a front side of a substrate.

In the front emission organic light emitting diode (OLED) display, the common electrode may be formed of a transparent conductive material, and almost all the light emitted by an inner emission layer may be transmitted from the organic light emitting diode (OLED) display. However, external light from the surroundings may enter the organic light emitting diode (OLED) display and undergo partial reflection at the different layers within the organic light emitting diode (OLED) display. The partial reflection of the incoming light may interfere with the image display. In particular, the partially reflected light may lower the visibility of black colors and cause the contrast ratio to deteriorate. To reduce the amount of light entering the organic light emitting diode (OLED) display from the external environment, a polarizing plate may be attached near an external surface of the organic light emitting diode (OLED) display.

However, the polarizing plate may affect the form factor of the organic light emitting diode (OLED) display because the polarizing plate may increase the overall thickness of the OLED display. Also, the polarizing plate may include a rigid plastic film that decreases the flexibility of the OLED display. Furthermore, the polarizing plate adds cost and may lower the price competitiveness of the OLED display.

Recently, display devices having touch sensing function have been developed. The touch sensing function allows the device to sense contact information, for example, whether contact with the display device has been made via a finger or a touch pen, as well as the contact position (if contact has been made). The touch sensing function enables a machine (e.g. a computer) to perform a desired command when a user writes or draws characters (or executes icons) on the display device by touching the display screen.

To enable the touch sensing function, a touch screen panel including a touch sensor may be attached to the external surface of the organic light emitting diode (OLED) display. However, as with the polarizing plate, the touch screen panel and touch sensor may increase form factor and cost, and lower the flexibility of the OLED display.

### SUMMARY

The present disclosure is directed to address at least the above deficiencies in the related art.

According to some embodiments of the inventive concept, an organic light emitting diode (OLED) display is provided. The organic light emitting diode (OLED) display includes an insulation substrate having a first surface and a second surface opposite to the first surface; an organic light emitting element disposed on the first surface of the insulation substrate; and an upper thin film disposed on the organic light emitting element or on the second surface of the insulation substrate, wherein the upper thin film includes a contact sensing layer and a thin multi-film adjacent to the contact sensing layer, and the thin multi-film includes at least one thin metal film and at least one dielectric layer.

In some embodiments, the contact sensing layer may include a plurality of first sensing electrodes extending in a first direction and a plurality of second sensing electrodes extending in a second direction crossing the first direction.

In some embodiments, the contact sensing layer may further include an insulation layer disposed between the first sensing electrodes and the second sensing electrodes.

In some embodiments, the insulation layer may be disposed as a continuous layer within the contact sensing layer.

In some embodiments, the insulation layer may include a plurality of insulating islands disposed at regions where the first sensing electrodes cross the second sensing electrodes.

In some embodiments, the insulation layer may include a plurality of insulating islands extending along the first sensing electrode or the second sensing electrode.

In some embodiments, a width of the insulating island may be greater than or equal to a width of the first sensing electrode or the second sensing electrode.

In some embodiments, the first sensing electrode and the second sensing electrode may form a self-sensing capacitor, wherein the self-sensing capacitor is configured to receive a sensing input signal, and to output a sensing output signal when an external object makes contact with the upper thin film.

In some embodiments, the first sensing electrode and the second sensing electrode may form a mutual sensing capacitor, wherein the first sensing electrode and the second sensing electrode are adjacent to or overlapping each other, the first sensing electrode is configured to receive a sensing input signal, and the second sensing electrode is configured to output a sensing output signal when an external object makes contact with the upper thin film.

In some embodiments, the thin metal film adjacent to the contact sensing layer may include the plurality of first sensing electrodes or the plurality of second sensing electrodes of the contact sensing layer.

In some embodiments, the organic light emitting diode (OLED) display may further include a pixel definition layer disposed on the organic light emitting element, the pixel definition layer defining a pixel area.

In some embodiments, at least one of the plurality of first sensing electrodes and the plurality of second sensing electrodes may overlap the pixel definition layer.

In some embodiments, the thin metal film may include at least one of Cr, Ti, Mo, Co, Ni, W, Al, Ag, Au, Cu, Fe, Mg, and Pt.

In some embodiments, the dielectric layer may include at least one of SiOx (x≧1), Al₂O₃, SnO₂, ITO, IZO, ZnO, Ta₂O₅, Nb₂O₅, HfO₂, TiO₂, In₂O₃, SiNₓ (x≧1), MgF₂, and CaF₂.

According to some other embodiments of the inventive concept, a method of manufacturing an organic light emitting diode (OLED) display is provided. The method includes forming an organic light emitting element on a first surface of an insulation substrate, wherein the first surface is opposite to a second surface of the insulation substrate; forming a contact sensing layer on the organic light emitting element or on the second surface of the insulation substrate; and forming a thin multi-film on the contact sensing layer or on the second surface of the insulation substrate, wherein forming the thin multi-film comprises alternately depositing at least one thin metal film and at least one dielectric layer.

In some embodiments, forming the contact sensing layer may include forming a plurality of first sensing electrodes extending in a first direction; forming an insulation layer on the first sensing electrodes; and forming a plurality of second sensing electrodes on the insulation layer, wherein the second sensing electrodes extend in a second direction crossing the first direction.

In some embodiments, forming the insulation layer may include depositing an insulating material on the first sensing electrodes, and patterning the insulating material to form a plurality of insulating islands disposed at regions where the first sensing electrodes cross the second sensing electrodes.

In some embodiments, forming the insulation layer may further include depositing an insulating material on the first sensing electrodes, and patterning the insulating material to form a plurality of insulating islands extending along the first sensing electrode or the second sensing electrode.

In some embodiments, the thin metal film may include at least one of Cr, Ti, Mo, Co, Ni, W, Al, Ag, Au, Cu, Fe, Mg, and Pt, and the dielectric layer may include at least one of SiOₓ (x≧1), Al₂O₃, SnO₂, ITO, IZO, ZnO, Ta₂O₅, Nb₂O₅, HfO₂, TiO₂, In2O3, SiNx (x≧1), MgF₂, and CaF₂.

### BRIEF DESCRIPTION OF THE DRAWINGS

FIG. 1 shows an equivalent circuit of a pixel of an organic light emitting diode (OLED) display according to an exemplary embodiment of the inventive concept.

FIG. 2 is a layout view of a pixel of an organic light emitting diode (OLED) display according to an exemplary embodiment.

FIG. 3 is a cross-sectional view of the organic light emitting diode (OLED) display of FIG. 2 taken along the line III-III.

FIG. 4 is a top plan view of an upper thin film of an organic light emitting diode (OLED) display according to an exemplary embodiment.

FIG. 5 is a cross-sectional view of the upper thin film of FIG. 4 taken along the line V-V.

FIG. 6 is a detailed cross-sectional view of the thin multi-film of FIG. 5 according to an exemplary embodiment.

FIG. 7 is a top plan view of an upper thin film of an organic light emitting diode (OLED) display according to another exemplary embodiment.

FIG. 8 is a cross-sectional view of the upper thin film of FIG. 7 taken along the line VIII-VIII.

FIG. 9 is a top plan view of an upper thin film of an organic light emitting diode (OLED) display according to a further exemplary embodiment.

FIG. 10 is a cross-sectional view of an upper thin film of an organic light emitting diode (OLED) display according to another further exemplary embodiment.

FIG. 11 is a detailed cross-sectional view of the upper thin film of FIG. 10.

### DETAILED DESCRIPTION

The inventive concept will be described more fully herein with reference to the accompanying drawings, in which exemplary embodiments of the inventive concept are shown. As those skilled in the art would realize, the embodiments may be modified in various ways without departing from the spirit or scope of the present disclosure.

In the drawings, the thickness of layers, films, panels, regions, etc., may have been exaggerated for clarity. Like reference numerals designate like elements throughout the specification. It will be understood that when an element such as a layer, film, region, or substrate is referred to as being disposed “on” another element, it can be disposed directly on the other element, or disposed on the other element with one or more intervening elements being present. In contrast, when an element is referred to as being disposed “directly on” another element, there are no intervening elements present.

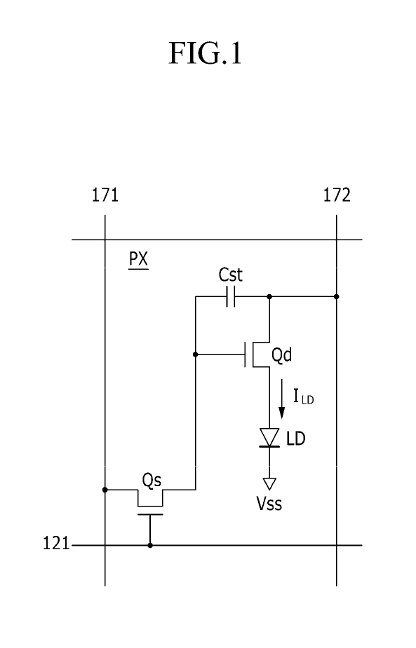

FIG. 1 shows an equivalent circuit of a pixel of an organic light emitting diode (OLED) display according to an exemplary embodiment of the inventive concept.

Referring to FIG. 1, an organic light emitting diode (OLED) display includes a plurality of signal lines and a plurality of pixels PX connected to the signal lines. The pixels may be arranged substantially in a matrix (not shown).

The signal lines include a plurality of scan signal lines 121 for transmitting gate signals (or scanning signals), a plurality of data lines 171 for transmitting data signals, and a plurality of driving voltage lines 172 for transmitting a driving voltage. The scan signal lines 121 extend substantially in a row direction and are substantially parallel to each other. The data lines 171 and the driving voltage lines 172 extend substantially in a column direction and are substantially parallel to each other. In some embodiments (not shown), the driving voltage lines 172 may extend in a row direction or a column direction to form a matrix.

Each pixel PX includes a switching transistor Qs, a driving transistor Qd, a storage capacitor Cst, and an organic light emitting element LD.

The switching transistor Qs includes a control terminal, an input terminal, and an output terminal. The control terminal of the switching transistor Qs is connected to a scan signal line 121; the input terminal of the switching transistor Qs is connected to a data line 171; and the output terminal of the switching transistor Qs is connected to the driving transistor Qd. The switching transistor Qs receives a data signal from the data line 171 and transmits the data signal to the driving transistor Qd, in response to a scanning signal received from the scan signal line 121.

Similar to the switching transistor Qs, the driving transistor Qd includes a control terminal, an input terminal, and an output terminal. The control terminal of the driving transistor Qd is connected to the switching transistor Qs; the input terminal of the driving transistor Qd is connected to a driving voltage line 172; and the output terminal of the driving transistor Qd is connected to the organic light emitting element LD. The driving transistor Qd applies an output current I_{LD} to the organic light emitting element LD. The magnitude of the output current I_{LD} may vary according to the voltage applied between the control terminal and output terminal of the driving transistor Qd.

The storage capacitor Cst is connected between the control terminal and input terminal of the driving transistor Qd. The storage capacitor Cst stores the data signal applied to the control terminal of the driving transistor Qd, and maintains the stored data signal even after the switching transistor Qs is turned off.

The organic light emitting element LD includes an organic light emitting diode (OLED). The organic light emitting element LD may include an anode connected to the output terminal of the driving transistor Qd and a cathode connected to a common voltage Vss. The organic light emitting element LD emits light, and the intensity of the light emitted varies according to the output current I_{LD} of the driving transistor Qd, thereby displaying an image. The organic light emitting element LD may include an organic material emitting at least one of the primary colors (e.g. red, green, or blue) or a white color. In some embodiments, the organic light emitting device may emit a desired image based on a spatial sum of the colors.

The switching transistor Qs and the driving transistor Qd may be n-channel field effect transistors (FET). In some embodiments, at least one of the switching transistor Qs and the driving transistor Qd may be a p-channel FET. It should be noted that the connections between the transistors Qs and Qd, storage capacitor Cst, and organic light emitting element LD may be modified in various ways by one of ordinary skill in the art.

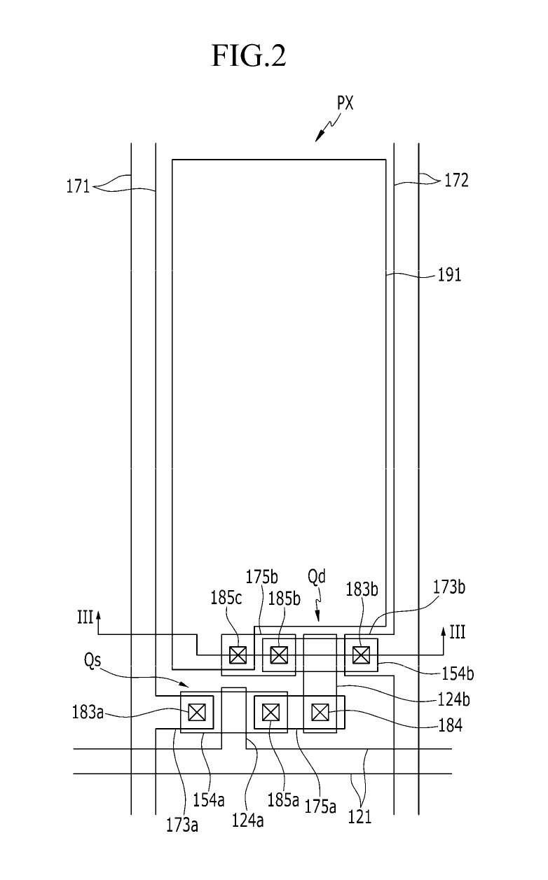

Next, the structure of an exemplary organic light emitting diode (OLED) display will be described with reference to FIGS. 2 to 6.

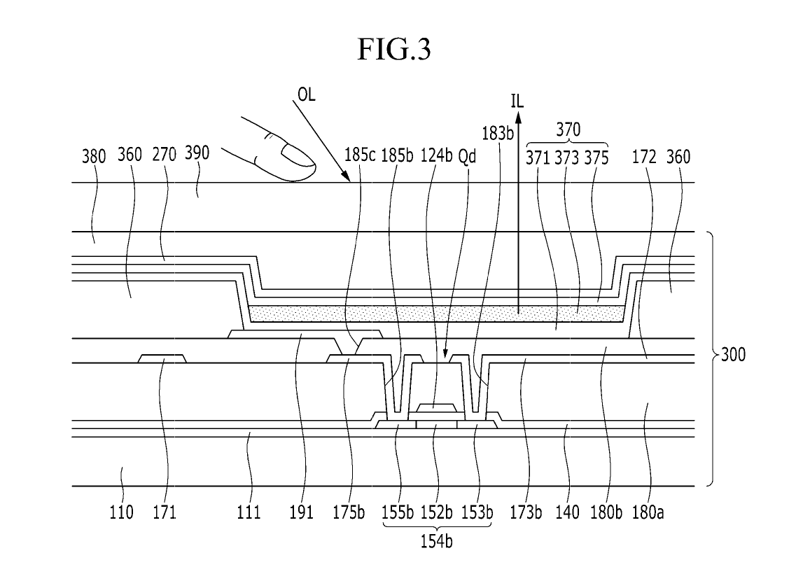

FIG. 2 is a layout view of a pixel of an organic light emitting diode (OLED) display according to an exemplary embodiment of the inventive concept. FIG. 3 is a cross-sectional view of the organic light emitting diode (OLED) display of FIG. 2 taken along the line III-III.

Referring to FIGS. 2 and 3, a buffer layer 111 is disposed on an insulation substrate 110. The insulation substrate 110 may be formed of glass or plastic. The buffer layer 111 serves to prevent diffusion of impurities into the insulation substrate 110. The buffer layer 111 also provides a flat surface on which subsequent layers are deposited. The buffer layer 111 may include silicon nitride (SiNₓ), silicon oxide (SiO₂), or silicon oxynitride (SiOₓN_{y}). In some particular embodiments, the buffer layer 111 may be omitted.

A plurality of first semiconductors 154a and second semiconductors 154b are disposed on the buffer layer 111. The first semiconductor 154a may include a channel region, and a source region and a drain region disposed on opposite sides of the channel region. (not shown). The channel region, source region, and drain region of the first semiconductor 154a may be doped with an impurity. The second semiconductor 154b may include a channel region 152b, and a source region 153b and a drain region 155b disposed on opposite sides of the channel region 152b. The channel region 152b, source region 153b, and drain region 155b of the second semiconductor 154b may be doped with an impurity. The first semiconductor 154a and the second semiconductor 154b may include amorphous silicon, polysilicon, or an oxide semiconductor.

A gate insulating layer 140 is disposed on the first semiconductor 154a and the second semiconductor 154b. The gate insulating layer 140 may include silicon nitride (SiNₓ) or silicon oxide (SiO₂).

A plurality of gate conductors are disposed on the gate insulating layer 140. The gate conductors include a plurality of scan signal lines 121, a first control electrode 124a, and a second control electrode 124b.

The scan signal line 121 transmits a scan signal and extends primarily in a transverse direction. The first control electrode 124a may extend upward from the scan signal line 121. The second control electrode 124b is separated from the scan signal line 121 (i.e. the second control electrode 124b is not connected to the scan signal line 121). In some embodiments, the second control electrode 124b may include a storage electrode (not shown) extending in a longitudinal direction. The first control electrode 124a may overlap a portion (e.g. the channel region) of the first semiconductor 154a. The second control electrode 124b may overlap a portion (e.g. the channel region 152b) of the second semiconductor 154b.

A first protective layer 180a is disposed on the gate insulating layer 140 and a gate conductor. As shown in FIG. 3, the first protective layer 180a is disposed on the gate insulating layer 140 and the second control electrode 124b. The first protective layer 180a and the gate insulating layer 140 include contact holes 183a, 183b, 185a, and 185b. The contact holes 183a and 185a exposes the respective source region and drain region of the first semiconductor 154a. The contact holes 183b and 185b expose the respective source region 153b and drain region 155b of the second semiconductor 154b. The first protective layer 180a further includes a contact hole 184 exposing the second control electrode 124b.

A plurality of data conductors are disposed on the first protective layer 180a. The data conductors include a plurality of data lines 171, driving voltage lines 172, first output electrodes 175a, and second output electrodes 175b.

The data line 171 transmits a data voltage and extends primarily in the longitudinal direction crossing the scan signal line 121. Each data line 171 includes a plurality of first input electrodes 173a extending toward the first control electrode 124a.

The driving voltage line 172 transmits a driving voltage and extends primarily in the longitudinal direction crossing the scan signal line 121. Each driving voltage line 172 includes a plurality of second input electrodes 173b extending toward the second control electrode 124b. In some embodiments, the second control electrode 124b may include a storage electrode, and a portion of the driving voltage line 172 may overlap the storage electrode.

The first and second output electrodes 175a and 175b may be disposed as separate islands, and separated from the data line 171 and the driving voltage line 172. The first input electrode 173a and the first output electrode 175a may be disposed facing the first semiconductor 154a, and the second input electrode 173b and the second output electrode 175b may be disposed facing the second semiconductor 154b.

The first input electrode 173a and first output electrode 175a may be connected to the respective source region and drain region of the first semiconductor 154a through the contact holes 183a and 185a. The first output electrode 175a may be connected to the second control electrode 124b through the contact hole 184. The second input electrode 173b and second output electrode 175b may be connected to the respective source region 153b and drain region 155b of the second semiconductor 154b through the contact holes 183b and 185b.

The first semiconductor 154a, first control electrode 124a, first input electrode 173a, and first output electrode 175a collectively constitute the switching transistor Qs. The second semiconductor 154b, second control electrode 124b, second input electrode 173b, and second output electrode 175b collectively constitute the driving transistor Qd. It should be noted that the structure of the switching transistor Qs and the driving transistor Qd is not limited to the above-described embodiments, and may be modified in various ways by one of ordinary skill in the art.

A second protective layer 180b may be disposed on a data conductor. As shown in FIG. 3, the second protective layer 180b is disposed on the second output electrodes 175b, data line 171, and second electrode 173b. The second protective layer 180b may include an inorganic material such as silicon nitride or silicon oxide. The second protective layer 180b may be formed having a flat surface so as to increase the luminous efficiency of the organic light emitting element LD (that is formed on the second protective layer 180b). The second protective layer 180b includes a contact hole 185c exposing the second output electrode 175b.

A plurality of pixel electrodes 191 corresponding to the plurality of pixels PX are disposed on the second protective layer 180b. The pixel electrode 191 of each pixel PX is connected to the second output electrode 175b through the contact hole 185c in the second protective layer 180b. The pixel electrode 191 may include a semi-transparent conducting material or a reflective conducting material.

A pixel definition layer 360 (also referred to as a barrier rib) may be disposed on the second protective layer 180b. The pixel definition layer 360 includes a plurality of openings exposing the pixel electrode 191. Each opening in the pixel definition layer 360 (that exposes a pixel electrode 191) may define a pixel area. In some particular embodiments, the pixel definition layer 360 may be omitted.

A light emitting member 370 is disposed on the pixel definition layer 360 and the pixel electrode 191. The light emitting member 370 may include a first organic common layer 371, a plurality of emission layers 373, and a second organic common layer 375. The aforementioned layers in the light emitting member 370 may be sequentially deposited.

The first organic common layer 371 may include at least one of a hole injection layer (HIL) and a hole transport layer (HTL). In some embodiments, the first organic common layer 371 may be formed over the entire display area (where the pixels (PX) are disposed). In some other embodiments, the first organic common layer 371 may be selectively formed within the region of each pixel (PX).

The emission layer 373 may be disposed on the pixel electrode 191 of the corresponding pixel (PX). The emission layer 373 may include an organic material capable of emitting light of the primary colors (e.g. red, green, or blue). In some embodiments, the emission layer 373 may include a plurality of organic material layers capable of emitting light of different colors.

For example, a red organic emission layer may be deposited on the first organic common layer 371 of a red color pixel (PX), a green organic emission layer may be deposited on the first organic common layer 371 of a green color pixel (PX), and a blue organic emission layer may be deposited on the first organic common layer 371 of a blue color pixel (PX). However, the inventive concept is not limited to the above-described configuration. In some embodiments, an organic emission layer representing a primary color may be deposited on a pixel (PX) representing other different colors. In some further embodiments, the emission layer 373 may include a white emission layer representing white color.

The second organic common layer 375 may include at least one of an electron transport layer (ETL) and an electron injection layer (EIL). In some embodiments, the second organic common layer 375 may be formed over the entire display area (where the pixels (PX) are disposed). In some other embodiments, the second organic common layer 375 may be selectively formed within the region of each pixel (PX).

The first and second organic common layers 371 and 375 serve to improve the luminous efficiency of the emission layer 373. In some particular embodiments, one of the first and second organic common layers 371 and 375 may be omitted.

A common electrode 270 is formed on the light emitting member 370. As previously mentioned, a common voltage (Vss) is applied to the common electrode 270. The common electrode 270 may include a transparent conductive material (such as calcium (Ca), barium (Ba), magnesium (Mg), aluminum (Al), or silver (Ag)) that allows light to be transmitted.

The pixel electrode 191, light emitting member 370, and common electrode 270 of each pixel (PX) collectively constitute an organic light emitting element LD. In some embodiments, the pixel electrode 191 may function as a cathode and the common electrode 270 may function as an anode. In other embodiments, the pixel electrode 191 may function as an anode and the common electrode 270 may function as a cathode. In some embodiments, the storage electrode of the second control electrode 124b may overlap the driving voltage line 172 to form a storage capacitor Cst.

The organic light emitting diode (OLED) display may be a top emission type or a bottom emission type. As shown in FIG. 3, inner light IL is emitted by the emission layer 373. When the organic light emitting diode (OLED) display is of the top emission type, the inner light IL is transmitted through the top (front) side of the substrate 110 to display an image. When the organic light emitting diode (OLED) display is of the bottom emission type, the inner light IL is transmitted through the rear (bottom) side of the substrate 110. Therefore, when the organic light emitting diode (OLED) display is of the bottom emission type, the light transmittance properties of the pixel electrode 191 and the common electrode 270 may be modified accordingly (for example, the common electrode 270 may include a reflective material, and the pixel electrode 191 may include a semi-transparent or a transparent material).

An encapsulation layer 380 may be disposed on the common electrode 270. The encapsulation layer 380 encapsulates and protects the light emitting member 370 and the common electrode 270 from air and moisture. The encapsulation layer 380 may be formed having a flat upper surface. In some particular embodiments, the encapsulation layer 380 may be omitted.

As shown in FIG. 3, external light OL from the surroundings may impinge onto the organic light emitting diode (OLED) display. The external light OL may be reflected at various layers of the organic light emitting diode (OLED) display. Accordingly, in those embodiments in which the organic light emitting diode (OLED) display is of the top emission type, an upper thin film 390 may be disposed on the encapsulation layer 380 to eliminate or reduce the reflection of external light OL. In particular, the upper thin film 390 is disposed over an area where the inner light IL is transmitted, so as to eliminate or reduce the amount of reflected light in that area. Accordingly, the contrast ratio and visibility in the displayed image may be improved by implementing the upper thin film 390.

As shown in FIG. 3, an external object (e.g. a finger) may contact an upper surface of the upper thin film 390.

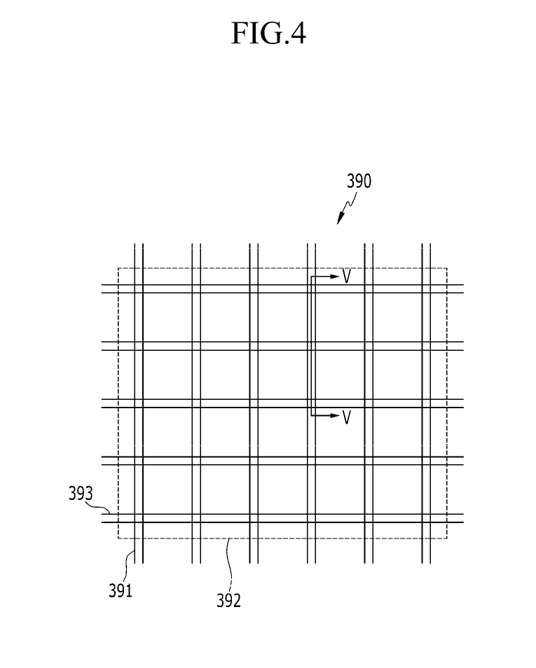

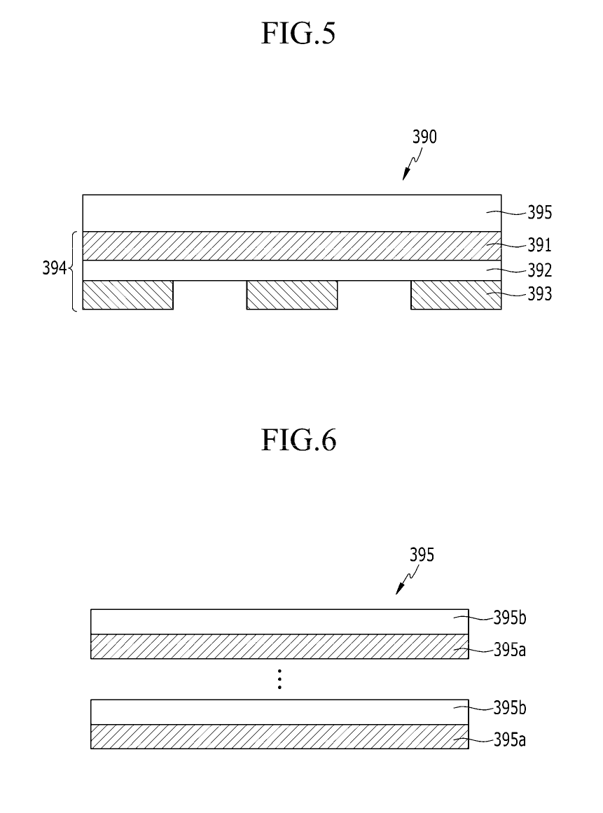

FIG. 4 is a top plan view of an upper thin film 390 of an organic light emitting diode (OLED) display according to an exemplary embodiment of the inventive concept. FIG. 5 is a cross-sectional view of the upper thin film 390 of FIG. 4 taken along the line V-V.

Referring to FIG. 5, the upper thin film 390 includes a contact sensing (touch detecting) layer 394 and a thin multi-film 395.

The contact sensing layer 394 includes a plurality of column sensing electrodes 391, a plurality of row sensing electrodes 393, and an insulation layer 392.

Referring to FIG. 4, the column sensing electrodes 391 are parallel to each other and extend in a column direction. The row sensing electrodes 393 are parallel to each other and extend in a row direction crossing the column sensing electrodes 391. The row sensing electrodes 393 are insulated from the column sensing electrodes 391 by the insulation layer 392. As shown in FIG. 5, the insulation layer 392 is disposed between the column sensing electrodes 391 and the row sensing electrodes 393.

At least one of the column sensing electrodes 391 and the row sensing electrodes 393 may overlap the pixel definition layer 360. In some embodiments, the column sensing electrodes 391 and the row sensing electrodes 393 need not overlap an opening of the pixel definition layer 360 corresponding to a pixel area. Instead, the column sensing electrodes 391 and the row sensing electrodes 393 may be disposed according to a light blocking region.

Each column sensing electrode 391 and row sensing electrode 393 form a capacitive contact sensor. When an external object makes contact with the capacitive contact sensor, the capacitance between the column sensing electrode 391 and the row sensing electrode 393 changes. Accordingly, the contact sensor can sense contact based on the change in capacitance. The contact position includes a row direction coordinate and a column direction coordinate. In some embodiments, the row direction coordinate of the contact position may be sensed using a plurality of column sensing electrodes 391 arranged in the row direction, and the column direction coordinate of the contact position may be sensed using a plurality of row sensing electrodes 393 arranged in the column direction.

In some embodiments, the column sensing electrode 391 and the row sensing electrode 393 may form a self-sensing capacitor Cs with a terminal from a different layer. In those embodiments, the column sensing electrode 391 and the row sensing electrode 393 are each charged with a predetermined amount of charge after receiving a sensing input signal. When an external object makes contact with the upper surface of the upper thin film 390, the amount of charge in the self-sensing capacitor Cs changes, and a sensing output signal is then generated from the sensing input signal. Contact information (such as contact position) may be obtained from the sensing output signal.

In some other embodiments, the column sensing electrode 391 and the row sensing electrode 393 that are adjacent to (or overlapping) each other may form a mutual sensing capacitor Cm. In those other embodiments, a sensing input signal is input to one of the column sensing electrode 391 and the row sensing electrode 393, while the other electrode (that does not receive the sensing input signal) outputs a sensing output signal according to a change in the amount of charge in the mutual sensing capacitor Cm when an external object makes contact with the upper surface of the upper thin film 390 Contact information (such as contact position) may be obtained from the sensing output signal.

The insulation layer 392 may be formed as a continuous layer within the contact sensing layer 394. As previously mentioned, the insulation layer 392 insulates the column sensing electrodes 391 from the row sensing electrodes 393.

FIG. 6 is a detailed cross-sectional view of the thin multi-film 395 of FIG. 5 according to an exemplary embodiment of the inventive concept.

Referring to FIG. 6, the thin multi-film 395 may include at least one thin metal film 395a and at least one dielectric layer 395b. The thin metal film 395a and dielectric layer 395b may be alternately disposed.

The thin metal film 395a may include a metal such as Cr, Ti, Mo, Co, Ni, W, Al, Ag, Au, Cu, Fe, Mg, or Pt, or alloys thereof.

The thickness of the dielectric layer 395b may be controlled so as to generate destructive optical interference. The dielectric layer 395b may include an oxide such as SiOₓ (x≧1), Al₂O₃, SnO₂, ITO, IZO, ZnO, Ta₂O₅, Nb₂O₅, HfO₂, TiO₂, In₂O₃, SiNₓ (x≧1), MgF₂, or CaF₂.

The thin multi-film 395 reduces the reflection of the external light OL in the organic light emitting diode (OLED) display, thereby improving the contrast ratio and the visibility of the image. Specifically, the external light OL undergoes destructive interference when it is reflected at the boundaries between the layers of the thin multi-film 395. The reflected light is also absorbed by the thin metal film 395a when the reflected light passes through the thin metal film 395a. Accordingly, the amount of external light OL that is reflected may be eliminated or reduced using the thin multi-film 395.

In some embodiments, the positions of the thin multi-film 395 and the contact sensing layer 394 (shown in FIG. 5) may be switched, such that the thin multi-film 395 is disposed below the contact sensing layer 394.

When the organic light emitting diode (OLED) display is of the bottom emission type, the relative positions of the elements in the organic light emitting diode (OLED) display in FIG. 3 may be modified, such that the insulation substrate 110 is disposed on an upper portion of the OLED display and the upper thin film 390 is disposed on the insulation substrate 110. In the above-described embodiment, an external object may make contact with the upper surface of the upper thin film 390.

Next, a method of manufacturing an organic light emitting diode (OLED) display according to an exemplary embodiment of the inventive concept will be described with reference to FIGS. 1 to 6.

First, a buffer layer 111 is formed on an upper surface of an insulation substrate 110. The buffer layer 111 may include silicon nitride, silicon oxide, or silicon oxynitride. The insulation substrate 110 may be formed of glass or plastic. In some particular embodiments, the buffer layer 111 may be omitted.

Next, a semiconductor layer is deposited and patterned on the buffer layer 111 to form a plurality of first semiconductors 154a and second semiconductors 154b. The semiconductor layer may include amorphous silicon, polysilicon, or an oxide semiconductor. The first semiconductors 154a and second semiconductors 154b are doped with an impurity. Each of the first semiconductors 154a includes a source region, a drain region, and a channel region. Each of the second semiconductors 154b includes a source region 153b, a drain region 155b, and a channel region 152b.

Next, a gate insulating layer 140 is formed on the first semiconductor 154a and the second semiconductor 154b. The gate insulating layer 140 may include silicon nitride (SiNₓ) or silicon oxide (SiO₂).

Next, a plurality of gate conductors are formed on the gate insulating layer 140. The gate conductors include a plurality of scan signal lines 121 having a first control electrode 124a and a second control electrode 124b. The gate conductors may include a metal such as aluminum, silver, or copper. The gate conductors may be deposited and patterned using photolithography.

Next, a first protective layer 180a is formed on the gate insulating layer 140 and the gate conductor. The first protective layer 180a may include an insulating material. Next, a plurality of contact holes 183a, 185a, 183b, 185b, and 184 are formed in the first protective layer 180a.

Next, a plurality of data conductors are formed on the first protective layer 180a. The data conductors include a conductive material (such as metal). The data conductors may formed using a sputtering method. The data conductors include a plurality of data lines 171, driving voltage lines 172, first output electrodes 175a, and second output electrodes 175b.

Next, a second protective layer 180b is formed on a data conductor. As shown in FIG. 3, the second protective layer 180b is formed on the second output electrode 175b, data line 171, and second electrode 173b. The second protective layer 180b may include an inorganic insulating material such as silicon nitride or silicon oxide. Next, a contact hole 185c is formed in the second protective layer 180b.

Next, a plurality of pixel electrodes 191 are formed on the second protective layer 180b. The pixel electrodes 191 may include a semi-transmissive or a reflective conducting material. For example, the pixel electrodes 191 may include a transparent conductive oxide (such as IZO or ITO) or a metal having high reflectance (such as silver (Ag) or aluminum (Al)).

Next, a pixel definition layer 360 is formed on the pixel electrode 191 and the second protective layer 180b. The pixel definition layer 360 may include a polyacrylate resin, a polyimide resin, or an inorganic silica material. The pixel definition layer 360 includes a plurality of openings exposing the respective pixel electrodes 191.

Next, a first organic common layer 371 is formed on the pixel definition layer 360 and the pixel electrode 191. Next, an emission layer 373 is formed in a region corresponding to the pixel electrode 191 of each pixel PX. Next, a second organic common layer 375 is formed on the emission layer 373. The first and second organic common layers 371 and 375 include an organic material, and the emission layer 373 includes a light emitting organic material. The first organic common layer 371, emission layer 373, and second organic common layer 375 collectively constitute a light emitting member 370. In some particular embodiments, at least one of the first and second organic common layers 371 and 375 may be omitted.

Next, a common electrode 270 is formed over the light emitting member 370. The common electrode 270 may include a transparent conductive material, or a thin metal film (comprising calcium (Ca), barium (Ba), magnesium (Mg), aluminum (Al), or silver (Ag)) that allows light to be transmitted.

Next, an encapsulation layer 380 may be formed on the common electrode 270, so as to encapsulate the organic light emitting member 370 and the common electrode 270. The encapsulation layer 380 may include at least one thin film formed of an insulating material.

Next, a plurality of row sensing electrodes 393 are formed on the encapsulation layer 380. The row sensing electrodes 393 may include a conductive material (such as a metal or a conductive oxide). Next, an insulation layer 392 is formed on the row sensing electrodes 393. The insulation layer 392 includes an insulating material and may be patterned using photolithography. Next, a plurality of column sensing electrodes 391 are formed on the insulation layer 392. The column sensing electrodes 391 may include a conductive material (such as a metal or a conductive oxide). The column sensing electrodes 391, row sensing electrodes 393, and insulation layer 392 collectively constitute a contact sensing layer 394.

Next, a thin multi-film 395 is formed on the column sensing electrode 391. The thin multi-film 395 includes at least one thin metal film 395a and at least one dielectric layer 395b that are alternately disposed. At this time, several deposition methods such as sputtering may be used. It should be noted that the deposition sequence of the thin metal film 395a and the dielectric layer 395b may be modified in different ways.

In some embodiments, the sequence for forming the contact sensing layer 394 and the thin multi-film 395 may be modified, such that the thin multi-film 395 is disposed below the contact sensing layer 394. In some further embodiments, the contact sensing layer 394 and the thin multi-film 395 may be formed on a lower surface of the insulation substrate 110 (opposite to the upper surface of the insulation substrate 110).

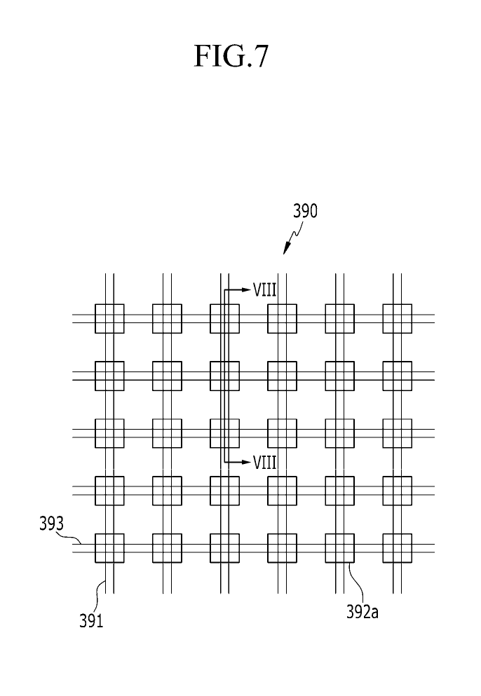

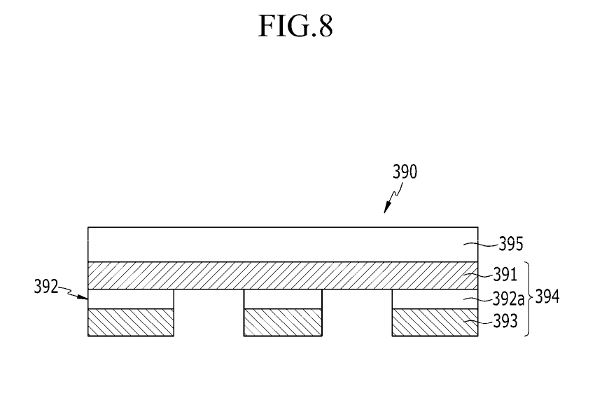

Next, an organic light emitting diode (OLED) display according to another exemplary embodiment of the inventive concept will be described with reference to FIGS. 7 and 8.

FIG. 7 is a top plan view of an upper thin film of an organic light emitting diode (OLED) display according to another exemplary embodiment. FIG. 8 is a cross-sectional view of the upper thin film of FIG. 7 taken along the line VIII-VIII.

The organic light emitting diode (OLED) display in FIGS. 7 and 8 is similar to the embodiments previously described in FIGS. 4 and 5 except for the differences described below.

Referring to FIG. 8, the insulation layer 392 is disposed between the column sensing electrodes 391 and the row sensing electrodes 393. However, as shown in FIGS. 7 and 8, the insulation layer 392 includes a plurality of insulating islands 392a formed in regions where the column sensing electrode 391 and the row sensing electrode 393 intersect with each other. The insulating islands 392a prevent electrical shorts between the column sensing electrodes 391 and the row sensing electrodes 393. As shown in FIG. 8, a first width of an insulating island 392a may be substantially the same as a first width of a row sensing electrode 393. As shown in FIG. 7, a second width of an insulating island 392a may be greater than a second width of the column sensing electrode 391 or the row sensing electrode 393. It should be noted that the shape of the insulating island 392a is not limited to the quadrangle shown in FIG. 7, and may include other shapes such as a circle or an ellipse.

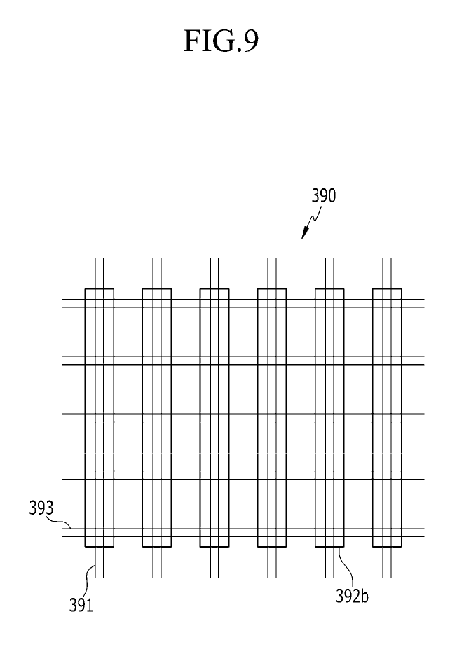

Next, an organic light emitting diode (OLED) display according to a further exemplary embodiment of the inventive concept will be described with reference to FIG. 9.

FIG. 9 is a top plan view of an upper thin film of an organic light emitting diode (OLED) display according to a further exemplary embodiment.

The organic light emitting diode (OLED) display in FIG. 9 is similar to the embodiment in FIGS. 7 and 8 except for the differences described below.

Referring to FIG. 9. the insulation layer 392 is disposed between the column sensing electrodes 391 and the row sensing electrodes 393. The insulation layer 392 includes a plurality of insulating islands 392b extending along (and overlapping) each column sensing electrode 391 or each row sensing electrode 393. Each insulating island 392b overlaps a region where a column sensing electrode 391 and a row sensing electrode 393 intersects, thus preventing electrical shorts between the column sensing electrodes 391 and the row sensing electrodes 393 in those regions. A width of the insulating island 392b may be equal to or greater than a width of the column sensing electrode 391 or the row sensing electrode 393.

Next, the differences between the embodiments of FIGS. 4 and 5 and the embodiments of FIGS. 7 to 9 will be described. In the embodiment of FIGS. 4 and 5, the insulation layer 392 is formed as a continuous layer within the contact sensing layer 394. In contrast, the insulation layer 392 in the embodiments of FIGS. 7 to 9 is not formed a continuous layer. Instead, as described above, the insulation layer 392 in FIGS. 7 to 9 comprises a plurality of insulation islands (392a or 392b) within the contact sensing layer 394. As a result, more light may be transmitted through the contact sensing layer 394 in the embodiments of FIGS. 7 to 9 compared to the embodiment of FIGS. 4 and 5.

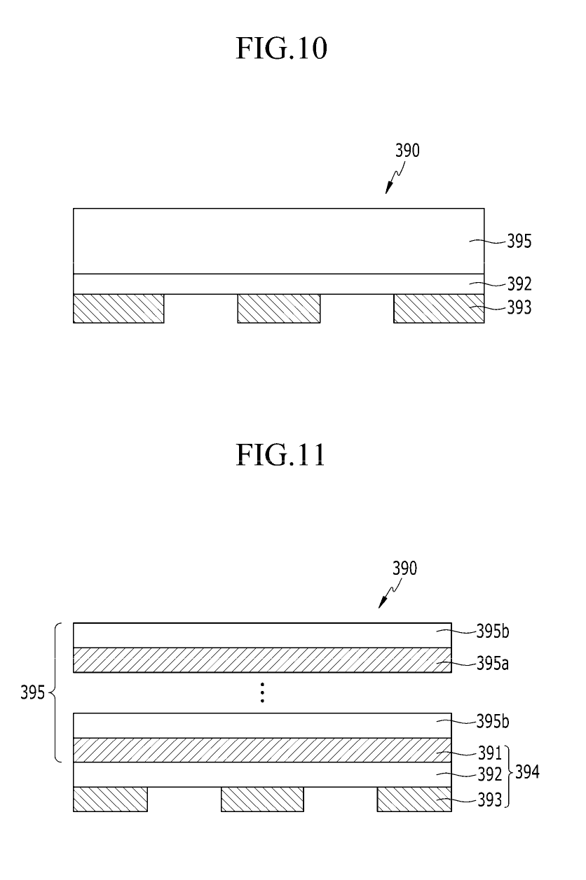

Next, an organic light emitting diode (OLED) display according to another further exemplary embodiment of the inventive concept will be described with reference to FIGS. 10 and 11.

FIG. 10 is a cross-sectional view of an upper thin film of an organic light emitting diode (OLED) display according to another further exemplary embodiment. FIG. 11 is a detailed cross-sectional view of the upper thin film of FIG. 10.

The organic light emitting diode (OLED) display in FIG. 10 is similar to the previously described embodiments except for the differences described below.

In the embodiment of FIGS. 10 and 11, the thin metal film 395a of the thin multi-film 395 (specifically the portion of the thin metal film 395a adjacent to the contact sensing layer 394) may serve two functions. First, the thin metal film 395a may function as a column sensing electrode 391 of the contact sensing layer 394. Second, the thin metal film 395a may reduce the partial reflection of the external light OL in the thin multi-film 395.

Accordingly, the thin multi-film 395 may eliminate or reduce reflection of the external light OL without the need for a polarizing plate. Additionally, the sensing electrodes (e.g. column sensing electrodes 391 and row sensing electrodes 393) may be formed on the thin multi-film 395, which eliminates the need for a separate touch screen panel with touch sensors. As previously mentioned, the polarizing plate and touch screen panel are relatively thick (which increases the form factor and decreases the flexibility of the OLED display) and add cost. Accordingly, the inventive concept allows the thickness and weight of the organic light emitting diode (OLED) display to be reduced, thereby improving the flexibility of the OLED display. The exemplary organic light emitting diode (OLED) display is also more cost-competitive, since a polarizing plate is no longer needed and because the exemplary manufacturing method is more streamlined (the thin-multi-film 395 can be formed using the same processes for fabricating the OLED display).

While this inventive concept has been described in connection with what is presently considered to be exemplary embodiments, it is to be understood that the inventive concept is not limited to the disclosed embodiments, but, on the contrary, is intended to cover various modifications and equivalent arrangements within the spirit and scope of the present disclosure.

What is claimed is:

1. An organic light emitting diode (OLED) display comprising:
an insulation substrate having a first surface and a second surface opposite to the first surface;
an organic light emitting element disposed on the first surface of the insulation substrate; and
an upper thin film disposed on the organic light emitting element or on the second surface of the insulation substrate,
wherein the upper thin film includes a contact sensing layer and a thin multi-film adjacent to the contact sensing layer, and
the thin multi-film includes at least one thin metal film and at least one dielectric layer.

2. The organic light emitting diode (OLED) display of claim 1, wherein the contact sensing layer includes a plurality of first sensing electrodes extending in a first direction and a plurality of second sensing electrodes extending in a second direction crossing the first direction.

3. The organic light emitting diode (OLED) display of claim 2, wherein the contact sensing layer further includes an insulation layer disposed between the first sensing electrodes and the second sensing electrodes.

4. The organic light emitting diode (OLED) display of claim 3, wherein the insulation layer is disposed as a continuous layer within the contact sensing layer.

5. The organic light emitting diode (OLED) display of claim 3, wherein the insulation layer includes a plurality of insulating islands disposed at regions where the first sensing electrodes cross the second sensing electrodes.

6. The organic light emitting diode (OLED) display of claim 5, wherein a width of the insulating island is greater than or equal to a width of the first sensing electrode or the second sensing electrode.

7. The organic light emitting diode (OLED) display of claim 3, wherein the insulation layer includes a plurality of insulating islands extending along the first sensing electrode or the second sensing electrode.

8. The organic light emitting diode (OLED) display of claim 7, wherein a width of the insulating island is greater than or equal to a width of the first sensing electrode or the second sensing electrode.

9. The organic light emitting diode (OLED) display of claim 2, wherein:
the first sensing electrode and the second sensing electrode form a self-sensing capacitor, wherein the self-sensing capacitor is configured to receive a sensing input signal, and to output a sensing output signal when an external object makes contact with the upper thin film.

10. The organic light emitting diode (OLED) display of claim 2, wherein:
the first sensing electrode and the second sensing electrode form a mutual sensing capacitor, wherein the first sensing electrode and the second sensing electrode are adjacent to or overlapping each other, and
the first sensing electrode is configured to receive a sensing input signal, and the second sensing electrode is configured to output a sensing output signal when an external object makes contact with the upper thin film.

11. The organic light emitting diode (OLED) display of claim 2, wherein:
the thin metal film adjacent to the contact sensing layer includes the plurality of first sensing electrodes or the plurality of second sensing electrodes of the contact sensing layer.

12. The organic light emitting diode (OLED) display of claim 2, further comprising a pixel definition layer disposed on the organic light emitting element, the pixel definition layer defining a pixel area.

13. The organic light emitting diode (OLED) display of claim 12, wherein at least one of the plurality of first sensing electrodes and the plurality of second sensing electrodes overlaps the pixel definition layer.

14. The organic light emitting diode (OLED) display of claim 1, wherein the thin metal film includes at least one of Cr, Ti, Mo, Co, Ni, W, Al, Ag, Au, Cu, Fe, Mg, and Pt.

15. The organic light emitting diode (OLED) display of claim 1, wherein the dielectric layer includes at least one of SiOx (x≧1), Al₂O₃, SnO₂, ITO, IZO, ZnO, Ta₂O₅, Nb₂O₅, HfO₂, TiO₂, In₂O₃, SiNₓ (x≧1), MgF₂, and CaF₂.

16. A method of manufacturing an organic light emitting diode (OLED) display, the method comprising:
forming an organic light emitting element on a first surface of an insulation substrate, wherein the first surface is opposite to a second surface of the insulation substrate;
forming a contact sensing layer on the organic light emitting element or on the second surface of the insulation substrate; and
forming a thin multi-film on the contact sensing layer or on the second surface of the insulation substrate,
wherein forming the thin multi-film comprises alternately depositing at least one thin metal film and at least one dielectric layer.

17. The method of claim 16, wherein forming the contact sensing layer comprises:
forming a plurality of first sensing electrodes extending in a first direction;
forming an insulation layer on the first sensing electrodes; and
forming a plurality of second sensing electrodes on the insulation layer,
wherein the second sensing electrodes extend in a second direction crossing the first direction.

18. The method of claim 17, wherein forming the insulation layer comprises:
depositing an insulating material on the first sensing electrodes; and
patterning the insulating material to form a plurality of insulating islands disposed at regions where the first sensing electrodes cross the second sensing electrodes.

19. The method of claim 17, wherein forming the insulation layer further comprises:
depositing an insulating material on the first sensing electrodes; and
patterning the insulating material to form a plurality of insulating islands extending along the first sensing electrode or the second sensing electrode.

20. The method of claim 16, wherein the thin metal film includes at least one of Cr, Ti, Mo, Co, Ni, W, Al, Ag, Au, Cu, Fe, Mg, and Pt; and
the dielectric layer includes at least one of SiOₓ (x≧1), Al₂O₃, SnO₂, ITO, IZO, ZnO, Ta₂O₅, Nb₂O₅, HfO₂, TiO₂, In2O3, SiNx (x≧1), MgF₂, and CaF₂.
